(19) United States
(12) Patent Application Publication
(10) Pub. No.: US 2016/0163551 A1
(43) Pub. Date: Jun. 9, 2016

(54) METHODS OF FORMING METAL SILICIDE REGIONS ON SEMICONDUCTOR DEVICES USING AN ORGANIC CHELATING MATERIAL DURING A METAL ETCH PROCESS

(71) Applicant: GLOBALFOUNDRIES Inc., Grand Cayman (KY)

(72) Inventors: Anh Duong, Fremont, CA (US); Tae-Hoon Kim, Malta, NY (US); Kakoli Das, Clifton Park, NY (US)

(21) Appl. No.: 14/560,479

(22) Filed: Dec. 4, 2014

(51) Int. Cl. H01L 21/283

(52) U.S. Cl. CPC H01L 21/283

(57) ABSTRACT

A method includes forming a refractory metal alloy layer above a silicon-containing material, performing a first heating process to form a metal silicide region in at least a portion of the silicon-containing material using the refractory metal alloy layer, and removing at least a first portion of an unreacted portion of the refractory metal alloy layer using a first solution comprising a solvent and an organic chelator.

### BACKGROUND OF THE INVENTION

1. Field of the Invention

Generally, the present disclosure relates to the manufacture of semiconductor devices, and, more specifically, to various methods of forming metal silicide regions on semiconductor devices using an organic chelating material during a metal etch process.

2. Description of the Related Art

The fabrication of advanced integrated circuits, such as CPUs, storage devices, ASICs (application specific integrated circuits) and the like, requires a large number of circuit elements to be formed on a given chip area according to a specified circuit layout, wherein field effect transistors represent one important type of circuit element that substantially determines performance of the integrated circuits. Generally, a plurality of process technologies are currently practiced, wherein, for many types of complex circuitry, including field effect transistors, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors (NMOS) and/or P-channel transistors (PMOS), are formed on a substrate including a crystalline semiconductor layer. A field effect transistor, irrespective of whether an NMOS transistor or a PMOS transistor is considered, typically comprises so-called PN junctions that are formed by an interface of highly doped regions, referred to as drain and source regions, with a slightly doped or non-doped region, such as a channel region, disposed adjacent to the highly doped regions.

Device designers are under constant pressure to increase the operating speed and electrical performance of transistors and integrated circuit products that employ such transistors. Given that the gate length (the distance between the source and drain regions) on modern transistor devices may be approximately 30-50 nm, and that further scaling is anticipated in the future, device designers have employed a variety of techniques in an effort to improve device performance, e.g., the use of high-k dielectrics, the use of metal gate electrode structures, the incorporation of work function metals in the gate electrode structure and the use of channel stress engineering techniques on transistors (create a tensile stress in the channel region for NMOS transistors and create a compressive stress in the channel region for PMOS transistors). Stress engineering techniques typically involve the formation of specifically made silicon nitride layers that are selectively formed above appropriate transistors, i.e., a layer of silicon nitride that is intended to impart a tensile stress in the channel region of a NMOS transistor would only be formed above the NMOS transistors. Such selective formation may be accomplished by masking the PMOS transistors and then blanket depositing the layer of silicon nitride, or by initially blanket depositing the layer of silicon nitride across the entire substrate and then performing an etching process to selectively remove the silicon nitride from above the PMOS transistors. Conversely, for PMOS transistors, a layer of silicon nitride that is intended to impart a compressive stress in the channel region of a PMOS transistor is formed above the PMOS transistors. The techniques employed in forming such nitride layers with the desired tensile or compressive stress are well known to those skilled in the art.

In a field effect transistor, metal silicide regions are typically formed in the source/drain regions of a transistor to reduce the resistance when a conductive contact is formed to establish electrical connection to the source/drain regions. Such metal silicide regions may also be formed on a portion of a gate structure of the transistor prior to forming a gate contact. Metal silicide regions may be made using a variety of different refractory metals, e.g., nickel, platinum, cobalt, etc., or combinations thereof, and they may be formed using techniques that are well known to those skilled in the art. The typical steps used to form metal silicide regions are: (1) depositing a layer of refractory metal, performing an initial heating process causing the refractory metal to react with underlying silicon-containing material; (2) performing an etching process to remove unreacted portions of the layer of refractory metal; and (3) performing an additional heating process to form the final phase of the metal silicide. The formation of metal silicide regions is becoming even more important as device dimensions decrease with the associated incorporation of very shallow source/drain regions in advanced devices. More specifically, in newer generation devices, it is important to accurately control the thickness and location of the metal silicide regions to avoid problems such as so-called spiking and piping whereby electrical short circuits can occur, which may lead to reduced device performance or, in a worst case, complete device failure.

One refractory metal alloy used to form silicide layers is nickel-platinum (NiPt). The NiPt alloy improves the thermal and morphological stability of the silicide (NiPtSi). A difficulty with the process for forming NiPtSi is the etching process performed to remove unreacted portions of the NiPt alloy. A conventional silicide process flow for forming NiPtSi (10% Pt) includes forming a NiPt alloy layer over an exposed silicon surface, forming a cap layer (e.g., TiN) over the NiPt alloy layer, performing a first rapid thermal anneal (RTA1) process to react the alloy layer with the silicon, performing a first etch process to remove the cap layer, performing a second rapid thermal anneal (RTA2) process to convert the NiPtSi to a low resistivity state, and performing a second etch process to remove the unreacted NiPt residues. Aqua regia is known to be effective for removing the platinum residues. However, aqua regia is not selective toward other metals in the device, such as aluminum or TiN commonly used in metal gate electrode structures, so these other metal structures can be damaged during the aqua regia strip. The problems with the residue removal etch process are exacerbated when the platinum contribution in the alloy is increased (e.g., 15%). Damage to the other metal structures can cause reduced performance or faults in the devices.

The present disclosure is directed to various methods of forming metal silicide regions on semiconductor devices.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming silicide layers. A method includes forming a refractory metal alloy layer above a silicon-containing material, performing a first heating process to form a metal silicide region in at least a portion of the silicon-containing material using the refractory metal alloy layer, and removing at least a first portion of an unreacted portion of the refractory metal alloy layer using a first solution comprising a solvent and an organic chelator.

A method includes forming a refractory metal alloy layer above a silicon-containing material, performing a first heating process to form a metal silicide region in at least a portion of the silicon-containing material using the refractory metal alloy layer, and removing at least a first portion of an unreacted portion of the refractory metal alloy layer using a first solution comprising a solvent and acetic acid.

A method includes forming a refractory metal alloy layer above a silicon-containing material, forming a cap layer above the refractory metal alloy layer, performing a first heating process to form a metal silicide region in at least a portion of the silicon-containing material using the refractory metal alloy layer, removing the cap layer and at least a first portion of an unreacted portion of the refractory metal alloy layer using a first solution comprising a first solvent and an organic acid prior to removing the first portion, removing at least a second portion of the unreacted portion using a second solution comprising a second solvent and an organic chelator, and performing a second heating process to convert the metal silicide region to a low resistivity state.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1F depict one illustrative method of forming metal silicide regions on semiconductor devices by using an organic chelating material during a metal strip etch process; and

FIG. 2 is a diagram illustrating a chelate complex.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

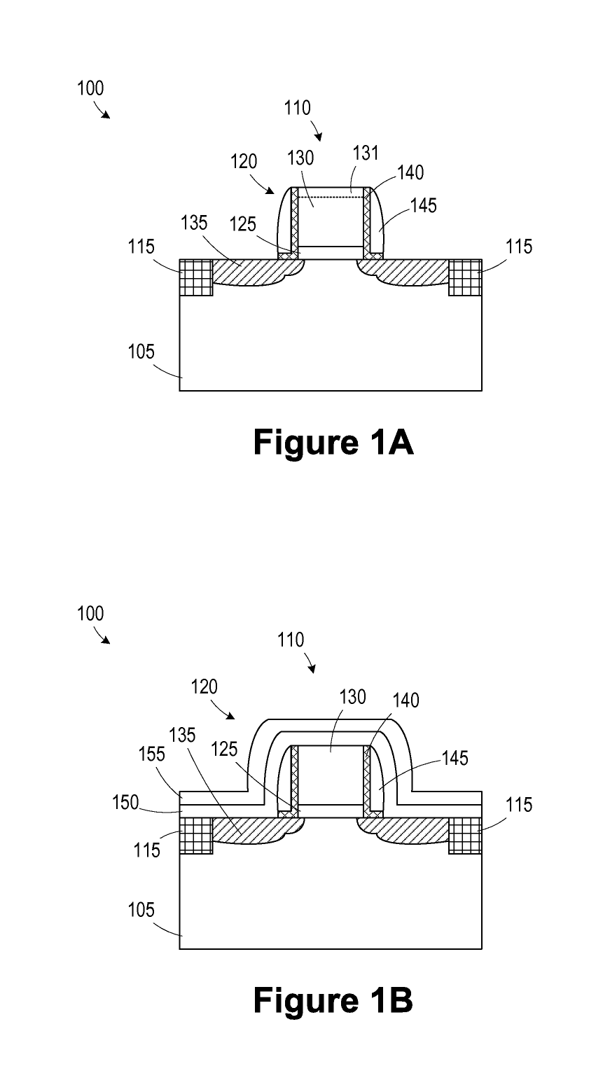

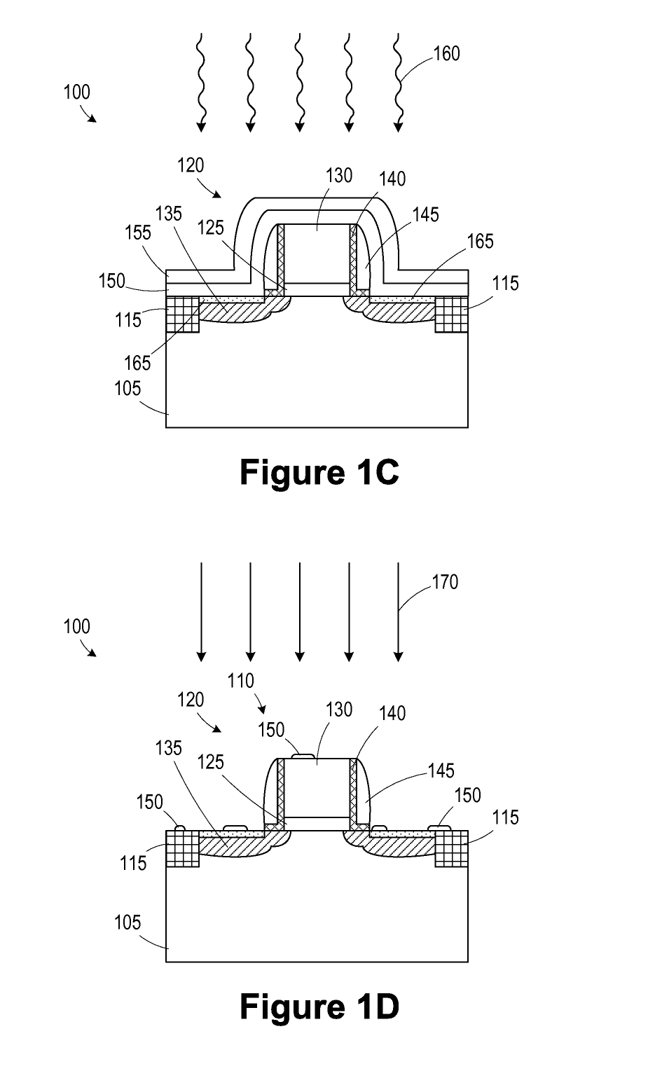

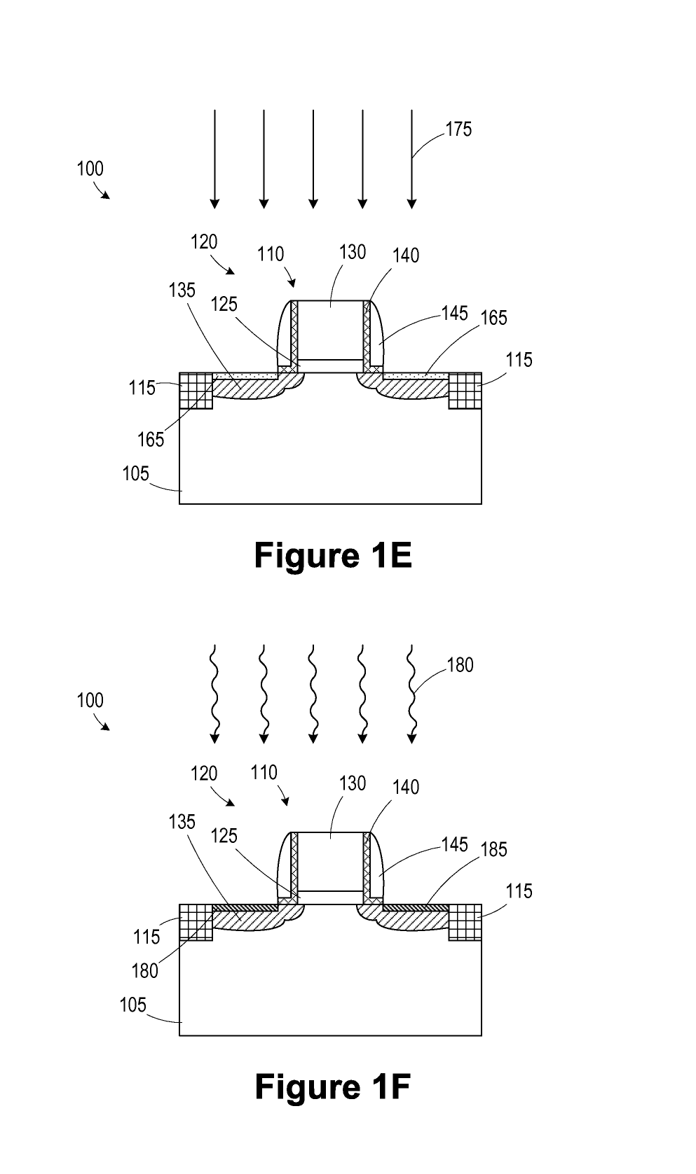

The present disclosure is directed to various methods of forming metal silicide regions on semiconductor devices by using an organic chelating material during a metal strip etch process while reducing or perhaps eliminating at least some of the problems discussed in the background section of this application. In some cases, the methods and devices may include a high-k dielectric material (k value greater than 10) and a metal-containing electrode material. As will be readily apparent to those skilled in the art upon a complete reading of the present application, the present method is applicable to a variety of technologies, e.g., NMOS, PMOS, CMOS, etc., and is readily applicable to a variety of devices, including, but not limited to, logic devices, memory devices, resistors, conductive lines, etc. With reference to FIGS. 1A-1F, various illustrative embodiments of the methods and devices disclosed herein will now be described in more detail.

FIG. 1A is a simplified view of an illustrative semiconductor device 100 at an early stage of manufacturing that is formed above a semiconducting substrate 105. The device 100 generally comprises an illustrative transistor 110 formed in and above the substrate 105. Illustrative trench isolation structures 115 are formed in the substrate 105. The substrate 105 may have a variety of configurations, such as the depicted bulk silicon configuration. The substrate 105 may also have a silicon-on-insulator (SOI) configuration that includes a bulk silicon layer, a buried insulation layer and an active layer, wherein semiconductor devices are formed in and above the active layer. Thus, the terms substrate or semiconductor substrate should be understood to cover all semiconductor structures. The substrate 105 may also be made of materials other than silicon.

At the point of fabrication depicted in FIG. 1A, the transistor 110 includes a schematically depicted gate electrode structure 120 that typically includes an illustrative gate insulation layer 125 and an illustrative gate electrode 130. The gate insulation layer 125 may be comprised of a variety of different materials, such as, for example, silicon dioxide, a so-called high-k (k greater than 10) insulation material, etc. Similarly, the gate electrode 130 may also be of a material such as polysilicon or amorphous silicon, or it may be comprised of one or more metal layers that act as the gate electrode 130. In some embodiments, a cap layer 131 (shown in phantom) may be formed above the gate electrode 130 if useful for protecting the gate electrode 130 from various processes to be performed. As will be recognized by those skilled in the art after a complete reading of the present application, the gate electrode structure 120 of the device 100 depicted in the drawings, i.e., the gate insulation layer 125 and the gate electrode 130, is intended to be representative in nature. That is, the gate electrode structures 120 may be comprised of a variety of different materials and they may have a variety of configurations, and the gate electrode structures 120 may be made using either so-called “gate-first” or “gate-last” techniques. In the illustrated embodiment, the illustrative transistor 110 is depicted as having a metal gate electrode 130, so the cap layer 131 is not necessary to protect the gate electrode 130 from silicidation processes and it is not illustrated in the subsequent figures, however, the present invention should not be considered as limited to such an illustrative embodiment.

Also as depicted in FIG. 1A, the transistor 110 also includes a plurality of source/drain regions 135, a liner layer 140 and a sidewall spacer 145 formed proximate the gate electrode structure 120. In one illustrative example, the liner layer 140 may be made of a material such as silicon dioxide, while the sidewall spacer 145 may be made of, for example, silicon nitride. The various structures and regions of the transistor 110 depicted in FIG. 1A may be formed by performing well-known processes. For example, the gate structures 120 may be formed by depositing various layer of material and thereafter performing one or more etching processes to define the basic layer stack of the gate electrode structures 120. The liner layer 140 may be comprised of a relatively thin layer of, for example, silicon dioxide, that is formed by performing a conformal chemical vapor deposition (CVD) process. The sidewall spacer 145 may be formed by depositing a layer of spacer material, such as silicon nitride, and thereafter performing an anisotropic etching process on the layer of spacer material. The source/drain regions 135 may be formed using known ion implantation techniques using the appropriate dopant materials, i.e., N-type dopants or P-type dopants, depending on the type of transistor 110 being fabricated.

Next, as shown in FIG. 1B a refractory metal alloy layer 150, such as a nickel-platinum (NiPt) layer, is formed above the transistor 110 on exposed surfaces of the source/drain regions 135. In the illustrated embodiment, the refractory metal alloy layer 150 includes nickel and platinum, with a platinum concentration of greater than 10%. More particularly, in one illustrative embodiment, the platinum concentration is about 15%. In some embodiments, other refractory metals may be substituted for the nickel component. A cap layer 155 (e.g., TiN) is formed above the refractory metal alloy layer 150. The thicknesses of the layers 150, 155 may vary depending upon the particular embodiment.

Next, as shown in FIG. 1C, a first heating or annealing process is performed, as schematically depicted by the arrows 160, to cause the refractory metal alloy layer 150 to react with surface portions of the source/drain regions 135 to form nickel-platinum-silicide (NiPtSi) regions 165. This annealing process 160 may be performed using a variety of techniques, such as a rapid thermal anneal (RTA) process, a laser anneal process, or a flash anneal process, etc. In one illustrative example, the annealing process 160 is an RTA process that is performed at a temperature of about 220°-300° C., and more particularly, 240-280° C., for a duration of about 30 seconds. Because the illustrative gate electrode 130 is metal, there is no reaction induced by the anneal process 160 thereon. If the gate electrode 130 were to be formed of polysilicon, and it was desired to prevent silicide from forming on the exposed surface of the gate electrode 130, the cap layer 131 (e.g., SiN) may be formed above the gate electrode 130.

Then, as shown in FIG. 1D, a first etch process is performed, as schematically depicted by the arrows 170, to remove the cap layer 155 and at least a portion of the unreacted refractory metal alloy layer 150. As simplistically depicted, some of the refractory metal alloy layer 150 remains after the first etch process. For example, a portion of the platinum may still remain. In some cases, some of the cap layer 155 (not shown) may also remain after the first etch process. In the illustrated embodiment, the first etch process 170 is performed using a solution of approximately equal parts of a solvent and an organic acid (e.g., acetic acid (CH₃COOH)). It has been determined that the solvent facilitates removal of the refractory metal alloy layer 150, and the acetic acid serves to protect the metal of the gate electrode 130 and the silicide regions 165 during the etch process. The solvent may be a strong acid (pH value of 2 or less) or a strong base (pH value of 12.5 or greater). In some embodiments, the solvent is an inorganic acid (e.g., nitric acid (HNO₃) or sulfuric acid (H₂SO₄)). In other embodiments, the solvent is a base, such as tetramethylammonium hydroxide (TMAH). In general, the first etch process 170 is well suited to remove nickel. However, in cases where the platinum concentration in the refractory metal alloy layer 150 is reduced (e.g., ≦10%), the etch process 170 may be sufficient to remove substantially all of the unreacted refractory metal alloy layer 150, and further etch processing may be avoided. In some embodiments, the organic acid (e.g., the acetic acid) may be omitted.

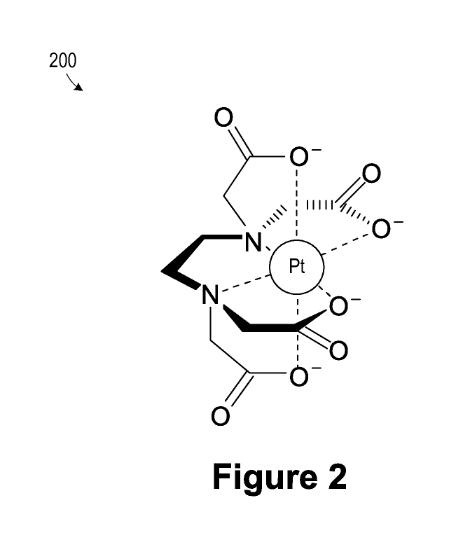

As shown in FIG. 1E, a second etch process is performed, as schematically depicted by the arrows 175, to remove the remnants of the refractory metal alloy layer 150. In the illustrated embodiment, the second etch process 175 is performed using a solution of a solvent, water (H₂O), and an organic chelator (e.g., oxalic acid, ascorbic acid, glycine, polyacrilic acid) using a ratio of approximately 0.5:0.4:0.05. The organic chelator forms a chelate complex 200 with platinum, as illustrated in FIG. 2. The chelate complex 200 has increased solubility in the solvent to facilitate removal of the platinum without attacking other metal features, such as the gate electrode 130. In some embodiments, the solvent may be an inorganic acid, such as hydrochloric acid (HCl), or an organic base, such as TMAH.

As shown in FIG. 1F, a second heating process (e.g., RTA) is performed, as schematically depicted by the arrows 180, to convert the silicide regions 165 to a low resistivity state, as depicted by low resistivity silicide regions 185. In one illustrative example, the annealing process 180 is an RTA process that is performed at a temperature of about 450° C. for a duration of about 30 seconds.

During the process flow depicted in FIGS. 1A-1F, additional rinses may be performed, such as a deionized water rinse, or a cleaning solution rinse. An example cleaning solution is commonly referred to as standard clean 1 (SC1), and includes deionized water, ammonium hydroxide (NH₄OH), and hydrogen peroxide (H₂O₂) (5:1:1). A cleaning process using SC1 generally removes organic contaminants, and may be performed after the second anneal 180 and/or after one or both of the etches 170, 175.

Thereafter, various additional processing operations may be performed to complete the fabrication of the device 100. Such processing operations include the formation of conductive contacts (not shown) and the formation of various metallization layers and structures (not shown) above the device 100.

The techniques for forming silicide layers described herein provide more complete removal of the unreacted portions of the refractory metal alloy layer 150. More specifically, in the case of increased platinum concentration alloy layers (≧15% Pt), the use of the organic chelator/solvent solution facilitates platinum removal while reducing damage to the other metal structures, such as the metal gate electrodes 130. Thus, using the techniques disclosed herein, the defects in the device 100 arising from unremoved platinum or damaged metal structures may be reduced.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a refractory metal alloy layer above a silicon-containing material;
performing a first heating process to form a metal silicide region in at least a portion of said silicon-containing material using said refractory metal alloy layer; and
removing at least a first portion of an unreacted portion of said refractory metal alloy layer using a first solution comprising a solvent and an organic chelator.

2. The method of claim 1, wherein forming said refractory metal alloy layer comprises forming said refractory metal alloy layer having a platinum concentration of greater than about 10%.

3. The method of claim 1, wherein forming said refractory metal alloy layer comprises forming said refractory metal alloy layer having a platinum concentration of greater than or equal to about 12%.

4. The method of claim 1, wherein forming said refractory metal alloy layer comprises forming said refractory metal alloy layer comprising nickel and platinum.

5. The method of claim 1, wherein said organic chelator comprises at least one of oxalic acid, ascorbic acid, glycine or polyacrilic acid.

6. The method of claim 1, wherein said solvent comprises hydrochloric acid.

7. The method of claim 1, wherein said solvent comprises tetramethylammonium hydroxide.

8. The method of claim 1, further comprising removing at least a second portion of said unreacted portion using a second solution comprising a solvent and organic acid prior to removing said first portion.

9. The method of claim 8, wherein said solvent comprises at least one of sulfuric acid or nitric acid, and said organic acid comprises acetic acid.

10. The method of claim 1, further comprising forming a cap layer above said refractory metal alloy layer prior to performing said first heating process.

11. The method of claim 10, further comprising removing said cap layer and at least a second portion of said unreacted portion using a second solution comprising a solvent and an organic acid prior to removing said first portion.

12. The method of claim 11, wherein said solvent comprises at least one of sulfuric acid or nitric acid, and said organic acid comprises acetic acid.

13. The method of claim 1, wherein performing said first heating process comprises performing said first heating process at a temperature range of between 220-300° C.

14. A method, comprising:
forming a refractory metal alloy layer above a silicon-containing material;
performing a first heating process to form a metal silicide region in at least a portion of said silicon-containing material using said refractory metal alloy layer; and
removing at least a first portion of an unreacted portion of said refractory metal alloy layer using a first solution comprising a solvent and acetic acid.

15. The method of claim 14, further comprising forming a cap layer above said refractory metal alloy layer prior to performing said first heating process.

16. The method of claim 15, further comprising removing said cap layer using said first solution.

17. The method of claim 14, wherein said solvent comprises at least one of sulfuric acid or nitric acid.

18. The method of claim 14, wherein forming said refractory metal alloy layer comprises forming said refractory metal alloy layer having a platinum concentration of less than or equal to about 10%.

19. The method of claim 14, wherein forming said refractory metal alloy layer comprises forming said refractory metal alloy layer comprising nickel and platinum.

20. A method, comprising:
forming a refractory metal alloy layer above a silicon-containing material;
forming a cap layer above said refractory metal alloy layer;
performing a first heating process to form a metal silicide region in at least a portion of said silicon-containing material using said refractory metal alloy layer;
removing said cap layer and at least a first portion of an unreacted portion of said refractory metal alloy layer using a first solution comprising a first solvent and an organic acid prior to removing said first portion;
removing at least a second portion of said unreacted portion using a second solution comprising a second solvent and an organic chelator; and
performing a second heating process to convert said metal silicide region to a low resistivity state.
